(19) United States
(12) Patent Application Publication
(10) Pub. No.: US 2017/0117422 A1
(43) Pub. Date: Apr. 27, 2017

(54) SILVER PASTE FOR SOLAR CELL AND METHOD FOR MAKING SAME

(71) Applicants: KANG ZHUN ELECTRONICAL TECHNOLOGY (KUNSHAN) CO., LTD., Kunshan (CN); HON HAI PRECISION INDUSTRY CO., LTD., New Taipei (TW)

(72) Inventors: HSIN-PEI CHANG, New Taipei (TW); WEN-RONG CHEN, New Taipei (TW); GUH-YAW JANG, New Taipei (TW); DI XU, Kunshan (CN); XUE-QUAN ZHAO, Kunshan (CN); DENG WANG, Kunshan (CN); SONG-SONG HE, Kunshan (CN); CHAO KE, Kunshan (CN)

(21) Appl. No.: 14/980,855

(22) Filed: Dec. 28, 2015

(30) Foreign Application Priority Data
Oct. 26, 2015 (CN) 201510702610.0

(51) Int. Cl. H01L 31/0224; C09D 5/24

(52) U.S. Cl. CPC H01L 31/022425; C09D 5/24

(57) ABSTRACT

A silver paste includes silver powder having a weight percentage of about 39% to about 60%, organic carrier having a weight percentage of about 35% to about 60%; and inorganic glass phase having a weight percentage of about 1% to about 5%. The inorganic glass phase includes a primary glass phase and inorganic additives. The primary glass phase includes bismuth oxide having a weight percentage of 10% to 40% in the inorganic glass phase, aluminum oxide having a weight percentage of 20% to 60% in the inorganic glass phase, and silicon oxide having a weight percentage of 10% to 30% in the inorganic glass phase.

### FIELD

The subject matter herein generally relates to a silver paste for back electrode of silicon solar cell and a method for making the silver paste.

### BACKGROUND

Nowadays, solar cells are widely used as a clean energy source. Solar cells usually need silver paste to form the back electrode.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series and the like.

A silver paste of an exemplary embodiment comprises silver powder having a weight percentage of about 39% to about 60%, inorganic glass phase having a weight percentage of about 1% to about 5%, and organic carrier having a weight percentage of about 35% to about 60%. The silver paste is configured for forming a back electrode for solar cells, especially for silicon solar cells. The silver powder in the silver paste acts as an electron-conductive matter. The inorganic glass phase in the silver paste acts as a binder and can provide enough binding strength between a back electrode made by the silver paste and a silicon wafer. The organic carrier causes the silver powder and the inorganic glass phase to disperse uniformly in the silver paste.

Particles of the silver powder can be flake-shaped or spherical. In this embodiment, particles of the silver powder are flake-shaped. The silver powder has a particle size in the range from 0.1 to 5 μm. Silver powder having a particle size in the range from 0.1 to 1 μm has a weight percentage of about 10% to about 30%, and silver powder having a particle size in the range from 1 to 5 μm has a weight percentage of about 70% to about 90%.

The inorganic glass phase comprises a primary glass phase and inorganic additives. The primary glass phase includes bismuth oxide having a weight percentage of about 10% to about 40% in the inorganic glass phase, aluminum oxide having a weight percentage of about 20% to about 60% in the inorganic glass phase, and silicon oxide having a weight percentage of about 10% to about 30% in the inorganic glass phase. The inorganic additives comprises at least two materials selected from a group consisting of copper oxide, zinc oxide, titanium oxide, manganese oxide, antimony oxide, magnesium oxide, lithium oxide, tin oxide, and nickel oxide. The inorganic additives can improve a tensile strength of the silver paste after welding.

In the inorganic glass phase, the copper oxide has a weight percentage of about 0% to about 10%, zinc oxide has a weight percentage of about 0% to about 40%, titanium oxide has a weight percentage of about 0% to about 5%, manganese oxide has a weight percentage of about 0% to about 10%, antimony oxide has a weight percentage about of 0% to about 1%, magnesium oxide has a weight percentage of about 0% to about 5%, tin oxide has a weight percentage of about 0% to about 5%, lithium oxide has a weight percentage of about 0% to about 5%, and nickel oxide has a weight percentage of about 0% to about 5%.

The organic carrier comprises an organic resin, a solvent, a defoamer agent, a plasticizer, a surfactant and a thixotropic agent. In the organic carrier, the organic resin has a weight percentage of about 8% to about 30%, the solvent has a weight percentage of about 60% to about 85%, the defoamer agent has a weight percentage about of 0.5% to about 1%, the plasticizer has a weight percentage about of 1% to about 5%, the surfactant has a weight percentage of about 0.5% to about 2%, the thixotropic agent has a weight percentage of about 0.5% to about 2%.

The organic resin comprises at least one selected from a group consisting of hydroxyethyl cellulose, acetyl butyryl cellulose, phenolic resin, and phenolic epoxy resin.

The solvent comprises at least one material selected from a group consisting of alpha-terpineol, ethelene glycol monophenyl ether, and diethylene glycol monobutyl ether.

The defoamer agent comprises at least one material selected from a group consisting of silicone oil and modified polyether. The defoamer agent can reduce surface tension of the organic carrier and reduce foam produced in the silver paste.

The plasticizer comprises at least one material selected from a group consisting of tributyl citrate, dimethyl phthalate, and 2-(2-butoxyethoxy)-ethanol acetate. The plasticizer can improve adhesion of the organic carrier.

The surfactant comprises at least one material selected from a group consisting of lecithin, polyoxyethylene sorbitan fatty acid ester and polyether. The surfactant can make the silver powder disperse uniformly in the organic carrier.

The thixotropic agent comprises at least one material selected from a group consisting of polyamide wax and castor oil hydrogenate. The thixotropic agent can make the silver paste thin when being stirred and dense when stationary.

An exemplary method for making a silver paste includes at least the following steps.

First, organic resin, solvent, defoamer agent, plasticizer, surfactant and thixotropic agent are mixed, heated to a temperature of about 80 to about 120° C. and stirred to be a uniform fluid mixture. The uniform fluid mixture is the organic carrier. In the organic carrier, the organic resin has a weight percentage of about 8% to about 30%, the solvent has a weight percentage of about 60% to about 85%, the defoamer agent has a weight percentage of about 0.5% to about 1%, the plasticizer has a weight percentage of about 1% to about 5%, the surfactant has a weight percentage of about 0.5% to about 2%, the thixotropic agent has a weight percentage of about 0.5% to about 2%.

Second, the silver powder, the inorganic glass phase and the organic carrier are mixed, stirred, and ground to form the silver paste. The silver powder has a weight percentage of about 39% to about 60%, the inorganic glass phase has a weight percentage of about 1% to about 5%, and the organic carrier has a weight percentage of about 35% to about 60%. The grinding step may use a three-roller grinding mill. In order to obtain a uniform silver paste, the silver paste can be ground 5 to 10 times. The silver paste has a fineness of less than 10 μm and a viscosity of about 20000 to about 50000 mpa·s.

The silver paste can be printed on a polycrystalline silicon wafer and be heated to form a back electrode. The printing of the silver paste uses a screen having 290 meshes. The polycrystalline silicon wafer may have a size of 156 mm×156 mm. The heating of the silver paste is carried out at a temperature of about 500 to about 940° C. in a furnace. The silicon solar cell using the silver paste may have average photoelectric transformation efficiency more than 18%. A solder ribbon is welded on the back electrode, and tension between the solder ribbon and the back electrode is tested to be more than 5 Newton.

### EXAMPLE 1

Hydroxyethyl cellulose, alpha-terpineol, silicone oil, 2-(2-butoxyethoxy)-ethanol acetate, polyoxyethylene sorbitan fatty acid ester, and polyamide wax were mixed, heated to a temperature of about 80 to about 120° C., and stirred to form an organic carrier. In the organic carrier, the hydroxyethyl cellulose had a weight percentage of 15%, the alpha-terpineol had a weight percentage of 77%, the silicone oil had a weight percentage of 1%, the 2-(2-butoxyethoxy)-ethanol acetate had a weight percentage of 5%, the polyoxyethylene sorbitan fatty acid ester had a weight percentage of 1%, the polyamide wax had a weight percentage of 1%.

An inorganic glass phase was formed by mixing bismuth oxide having a weight percentage of 27%, aluminum oxide having a weight percentage of 38%, and silicon oxide having a weight percentage of 20%, zinc oxide having a weight percentage of 12%, and manganese oxide having a weight percentage of 3%.

A silver powder having a weight percentage of 50%, the inorganic glass having a weight percentage of 3%, and the organic carrier having a weight percentage of 47% were mixed together to form the silver paste. The silver paste was stirred and ground by a three-roller grinding mill 5 times.

The silver paste was screen printed on a polycrystalline silicon wafer having a size of 156 mm×156 mm and was heated at a temperature of about 500 to about 940° C. for some time to form a back electrode. The printing of the silver paste used a screen having 290 mesh. The silicon solar cell using the silver paste had average photoelectric transformation efficiency of 18.04%. A solder ribbon was welded on the back electrode, and tension between the solder ribbon and the back electrode was tested to be 5.9 Newton.

### EXAMPLE 2

An organic carrier was formed by mixing hydroxyethyl cellulose, diethylene glycol monobutyl ether, silicone oil, tributyl citrate, lecithin, and castor oil hydrogenated together, heating to a temperature of about 80 to about 120° C., and stirring. In the organic carrier, the hydroxyethyl cellulose had a weight percentage of 17%, the diethylene glycol monobutyl ether had a weight percentage of 74.5%, the silicone oil had a weight percentage of 1%, the tributyl citrate had a weight percentage of 5%, the lecithin had a weight percentage of 0.5%, the castor oil hydrogenated had a weight percentage of 2%.

An inorganic glass phase was formed by mixing bismuth oxide having a weight percentage of 24%, aluminum oxide having a weight percentage of 38%, and silicon oxide having a weight percentage of 20%, zinc oxide having a weight percentage of 17%, and antimony oxide having a weight percentage of 1%.

A silver powder having a weight percentage of 55%, the inorganic glass phase having a weight percentage of 3.5%, and the organic carrier having a weight percentage of 41.5% were mixed together to form the silver paste. The silver paste was stirred and ground by a three-roller grinding mill 5 times.

The silver paste was screen printed on a polycrystalline silicon wafer having a size of 156 mm×156 mm and was heated at a temperature of about 500 to about 940° C. for some time to form a back electrode. The printing of the silver paste used a screen having 290 mesh. The silicon solar cell using the silver paste had an average photoelectric transformation efficiency of 18.06%. A solder ribbon was welded on the back electrode, and tension between the solder ribbon and the back electrode was tested to be 6.2 Newton.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A silver paste comprising:
silver powder having a weight percentage of about 39% to about 60%;
organic carrier having a weight percentage of about 35% to about 60%; and
inorganic glass phase having a weight percentage of about 1% to about 5%, the inorganic glass phase comprising a primary glass phase and inorganic additives, the primary glass phase comprising bismuth oxide having a weight percentage of about 10% to about 40% in the inorganic glass phase, aluminium oxide having a weight percentage of about 20% to about 60% in the inorganic glass phase, and silicon oxide having a weight percentage of about 10% to about 30% in the inorganic glass phase; the inorganic additives comprising at least two selected from a group consisting of copper oxide, zinc oxide, titanium oxide, manganese oxide, antimony oxide, magnesium oxide, lithium oxide, tin oxide, and nickel oxide.

2. The silver paste of claim 1, wherein in the inorganic glass phase, the copper oxide has a weight percentage of about 0% to about 10%, the zinc oxide has a weight percentage of about 0% to about 40%, the titanium oxide has a weight percentage of about 0% to about 5%, the manganese oxide has a weight percentage of about 0% to about 10%, the antimony oxide has a weight percentage of about 0% to about 1%, the magnesium oxide has a weight percentage of about 0% to about 5%, the tin oxide has a weight percentage of about 0% to about 5%, the lithium oxide has a weight percentage of about 0% to about 5%, and the nickel oxide has a weight percentage of about 0% to about 5%.

3. The silver paste of claim 1, wherein particles of the silver powder is flake-shaped or spherical.

4. The silver paste of claim 1, wherein the silver powder has a particle size in the range from 0.1 to 5 μm.

5. The silver paste of claim 4, wherein silver powder having a particle size in the range from 0.1 to 1 μm has a weight percentage of about 10% to about 30%, and silver powder having a particle size in the range from 1 to 5 μm has a weight percentage of about 70% to about 90%.

6. The silver paste of claim 1, wherein the organic carrier comprises organic resin, solvent, defoamer agent, plasticizer, surfactant and thixotropic agent.

7. The silver paste of claim 6, wherein in the organic carrier, the organic resin has a weight percentage of about 8% to about 30%, the solvent has a weight percentage of about 60% to about 85%, the defoamer agent has a weight percentage of about 0.5% to about 1%, the plasticizer has a weight percentage of about 1% to about 5%, the surfactant has a weight percentage of about 0.5% to about 2%, the thixotropic agent has a weight percentage of about 0.5% to about 2%.

8. The silver paste of claim 6, wherein the organic resin comprises at least one selected from a group consisting of hydroxyethyl cellulose, acetyl butyryl cellulose, phenolic resin, and phenolic epoxy resin; the solvent comprises at least one selected from a group consisting of alpha-terpineol, ethelene glycol monophenyl ether, and diethylene glycol monobutyl ether; the defoamer agent comprises at least one selected from a group consisting of silicone oil and modified polyether; the plasticizer comprises at least one selected from a group consisting of tributyl citrate, dimethyl phthalate, and 2-(2-butoxyethoxy)-ethanol acetate; the surfactant comprises at least one selected from a group consisting of lecithin, polyoxyethylene sorbitan fatty acid ester and polyether; the thixotropic agent comprises at least one selected from a group consisting of polyamide wax and castor oil hydrogenated.

9. The silver paste of claim 1, wherein the silver paste has a fineness of less than 10 μm and a viscosity of about 20000 to about 50000 mpa·s.

10. A method for making a silver paste comprising:
mixing silver powder, inorganic glass phase and organic carrier together to obtain a mixture, the silver powder having a weight percentage of about 39% to about 60% in the mixture, the organic carrier having a weight percentage of about 35% to about 60% in the mixture; and the inorganic glass phase having a weight percentage of about 1% to about 5% in the mixture, the inorganic glass phase comprising a primary glass phase and inorganic additives, the primary glass phase comprising bismuth oxide having a weight percentage of about 10% to about 40% in the inorganic glass phase, aluminium oxide having a weight percentage of about 20% to about 60% in the inorganic glass phase, and silicon oxide having a weight percentage of about 10% to about 30% in the inorganic glass phase; the inorganic additives comprising at least two selected from a group consisting of copper oxide, zinc oxide, titanium oxide, manganese oxide, antimony oxide, magnesium oxide, lithium oxide, tin oxide, and nickel oxide;
stirring and grinding the mixture to form the silver paste.

11. The method of claim 10, wherein the organic carrier is made by at least following steps:
mixing organic resin, solvent, defoamer agent, plasticizer, surfactant and thixotropic agent together to form an organic mixture;
heating the organic mixture to a temperature of about 80 to about 120° C. and stirring the organic mixture to be a uniform fluid.

12. The method of claim 11, wherein in the organic mixture, the organic resin has a weight percentage of about 8% to about 30%, the solvent has a weight percentage of about 60% to about 85%, the defoamer agent has a weight percentage of about 0.5% to about 1%, the plasticizer has a weight percentage of about 1% to about 5%, the surfactant has a weight percentage of about 0.5% to about 2%, the thixotropic agent has a weight percentage of about 0.5% to about 2%.

13. The method of claim 11, wherein the organic resin comprises at least one selected from a group consisting of hydroxyethyl cellulose, acetyl butyryl cellulose, phenolic resin, and phenolic epoxy resin; the solvent comprises at least one selected from a group consisting of alpha-terpineol, ethelene glycol monophenyl ether, and diethylene glycol monobutyl ether; the defoamer agent comprises at least one selected from a group consisting of silicone oil and modified polyether; the plasticizer comprises at least one selected from a group consisting of tributyl citrate, dimethyl phthalate, and 2-(2-butoxyethoxy)-ethanol acetate; the surfactant comprises at least one selected from a group consisting of lecithin, polyoxyethylene sorbitan fatty acid ester and polyether; the thixotropic agent comprises at least one selected from a group consisting of polyamide wax and castor oil hydrogenated.

14. The method of claim 10, wherein in the inorganic glass phase, the copper oxide has a weight percentage of about 0% to about 10%, the zinc oxide has a weight percentage of about 0% to about 40%, the titanium oxide has a weight percentage of about 0% to about 5%, the manganese oxide has a weight percentage of about 0% to about 10%, the antimony oxide has a weight percentage of about 0% to about 1%, the magnesium oxide has a weight percentage of about 0% to about 5%, the tin oxide has a weight percentage of about 0% to about 5%, the lithium oxide has a weight percentage of about 0% to about 5%, and the nickel oxide has a weight percentage of about 0% to about 5%.

15. The method of claim 10, wherein the silver powder has a particle size in the range from 0.1 to 5 μm, silver powder having a particle size in the range from 0.1 to 1 μm has a weight percentage of about 10% to about 30%, and silver powder having a particle size in the range from 1 to 5 μm has a weight percentage of about 70% to about 90%.
